(19) United States
(12) Patent Application Publication
(10) Pub. No.: US 2021/0079716 A1
(43) Pub. Date: Mar. 18, 2021

(54) SPACER FOR INSULATING GLAZINGS, COMPRISING AN ELECTRIC FEED LINE INTEGRATED INTO A HOLLOW CHAMBER

(71) Applicant: SAINT-GOBAIN GLASS FRANCE, COURBEVOIE (FR)

(72) Inventors: Marcus NEANDER, Eschweiler (DE); Guenael MORVAN, Marseille (FR); Hans-Werner KUSTER, Aachen (DE); Christopher MARJAN, Aachen (DE)

(21) Appl. No.: 16/963,733

(22) PCT Filed: Jan. 16, 2019
(86) PCT No.: PCT/EP2019/050992

§ 371 Date: Jul. 21, 2020

(30) Foreign Application Priority Data
Jan. 22, 2018 (EP) 18152707.8

(51) Int. Cl. E06B 3/663; E06B 3/67; E06B 3/673; E06B 9/24; G02F 1/161

(52) U.S. Cl. CPC E06B 3/66319; E06B 3/6722; E06B 3/67326; G02F 1/172; G02F 1/161; E06B 2009/2464; E06B 9/24

(57) ABSTRACT

A spacer has an integrated electric feed line for insulating glazings at least including a main body including two pane contact surfaces, a glazing interior surface, an outer surface, a hollow chamber, and an electric feed line within the hollow chamber, wherein the electric feed line enters the hollow chamber, runs along the hollow chamber substantially parallel to the pane contact surfaces in at least one section, and exits via at least one exit opening in the wall of the main body.

The invention relates to a spacer having an integrated electric feed line, an insulating glazing including such a spacer, a method for production thereof, and use thereof.

Insulating glazings have become indispensable in building construction, especially in the wake of ever stricter environmental protection regulations. These are made of at least two panes that are joined to one another via at least one circumferential spacer. Depending on the embodiment, the space between the two panes, referred to as the glazing interior, is air- or gas-filled, but free, in any case, of moisture. Excessive moisture content in the glazing interpane space results, in particular with cold outside temperatures, in condensation of water droplets in the interpane space, which must absolutely be avoided. To absorb the residual moisture remaining in the system after assembly, desiccant-filled hollow-body spacers can be used. However, since the absorption capacity of the desiccant is limited, sealing of the system is also of enormous importance to prevent penetration of further moisture.

Beyond their basic function, insulating glazings can also contain further elements in the form of built-in components or panes with controllable additional functions. Glazings with switchable or controllable optical properties are one type of modern, active glazings. With such glazings, for example, the transmittance of light can be actively influenced as a function of an applied electrical voltage. The user can, for example, switch from a transparent to a non-transparent state of the glazing to prevent vision into the room from the outside. With other glazings, the transmittance can be infinitely adjusted, for example, to regulate the entry of solar energy into a room. Thus, undesirable heating of buildings or vehicle interiors is avoided and the energy consumption or CO₂ emissions caused by air conditioning systems is reduced. Consequently, active glazings are used not only for the visually appealing designing of facades and pleasant lighting in the interior, but are also advantageous from an energy and ecology standpoint.

Active glazings contain a functional element, which typically contains an active layer between two surface electrodes. The optical properties of the active layer can be changed by a voltage applied to the surface electrodes. Electrochromic functional elements, known, for example, from US 20120026573 A1 and WO 2012007334 A1 are an example of this. SPD functional elements (suspended particle device), known, for example, from EP 0876608 B1 and WO 2011033313 A1 are another example. The transmittance of visible light through electrochromic or SPD functional elements can be controlled by the voltage applied. The voltage feed is done via so-called busbars, which are usually applied to the surface electrodes and are connected to a voltage source via suitable connection cables.

When an active glazing is integrated in an insulating glazing, the voltage feed of the active glazing must be designed gas- and water-tight in order to ensure sufficient quality and service life of the insulating glazing. In WO 2017/106458 A1, the electric feed line itself is designed in shape and size such that it has high tolerance against relative movements with differing thermal expansion of the components involved. However, the feed line itself is made between the spacer and an adjacent pane through the primary sealant used for bonding and sealing. Such a passage of cable through the edge seal of the insulating glazing always also constitutes a potential defect site.

Moreover, in practice, electrical contact is often necessary at multiple locations of the insulating glazing. The prior art connection cable is routed around the spacer frame in the outer interpane space. The spacer is is bonded to the panes of the insulating glazing via a so-called primary sealant, whereas a secondary sealant is introduced into the outer interpane space, filling it and surrounding any electrical connection cables that may be present. However, automated filling of the outer interpane space in the presence of electrical connection cables has proved problematic since they can, for example, spatially obstruct a robot arm with an extrusion nozzle. Furthermore, no air bubbles must remain in the outer interpane space, for example, between the connection cable and the spacer. The volume of the enclosed air varies with changing climatic conditions and permanently results in leaks of the insulating glazing in the region of the air inclusion.

A wide variety of modifications in the region of the spacer to ensure improved tightness of insulating glazings are already known. One measure for improving the tightness of insulating glazings is the coating of polymeric spacers with metal foils or alternating metal-polymer layer systems, as disclosed, for example, in EP 0 852 280 A1 and WO 2013/104507 A1. These ensure high tightness of the spacer with, at the same time, compatibility with the sealants used for assembly. However, the problems mentioned with regard to tightness of insulating glazings with electrical feed lines are not affected thereby.

DE 3330305 A1 describes a window with a composite glass pane held in the frame, wherein the composite pane includes an electrically controllable liquid crystal element. The control circuit is powered by an accumulator which is recharged by a solar cell arrangement.

U.S. Pat. No. 4,306,140 deals with the problem of electrically contacting a transparent conductive coating via the edge seal of a refrigerated shelf glazing, wherein physical contact with current-carrying parts must be prevented in the event of breakage of the glazing.

U.S. Pat. No. 4,691,486 A1 describes an insulating glazing with a heatable pane including an edge seal with hollow profile spacers that are connected via corner connectors at the corners, wherein the electrical contacting of the heatable pane is done via the edge seal by a cable passageway in the corner connectors.

The object of the present invention is to provide a spacer that results in improved sealing of insulating glazings having electrical feed lines, an insulating glazing with this spacer, and an economical method for producing the insulating glazing.

The object of the present invention is accomplished according to the invention by a spacer having an integrated electric feed line, an insulating glazing with a spacer, a method for production thereof, and use of the spacer according to the independent claims 1, 9, 10, 13, and 15. Preferred embodiments of the invention emerge from the dependent claims.

The spacer according to the invention having an integrated electric feed line for insulating glazings comprises at least one main body comprising two pane contact surfaces, a glazing interior surface, an outer surface, and at least one hollow chamber. The electric feed line runs within the hollow chamber of the spacer. The electric feed line runs, after entry into the hollow chamber in at least one section, along the hollow chamber within this hollow chamber. In this context, “along the hollow chamber” means in the longitudinal direction of the hollow chamber, i.e., substantially parallel to the pane contact surfaces. The electric feed line exits again from the hollow chamber through at least one exit opening in the wall of the main body.

The spacer according to the invention enables industrially automatable further processing of a spacer frame including the spacer according to the invention. Since the feed line is routed within the hollow chamber, automated filling of the edge region of the glazing can occur without the electric feed line constituting an obstacle for a material nozzle routed along the outer side of the spacer. Furthermore, with the exception of the point at which it enters or exits the main body, the feed line is not visible from the outside and is thus also integrated in an optically unobtrusive manner.

In the context of the invention, the spacer having an integrated electric feed line is used in particular when, for example, a voltage supply is necessary at multiple points of the insulating glazing and the distance between these points has to be bridged by an electrical conductor.

The structure according to the invention further constitutes a substantial improvement in terms of the tightness of insulating glazings. In the prior art, electric feed lines are routed into the glazing interior between one of the pane contact surfaces and the adjacent pane within the sealant that bonds these components to one another. Any cable passageway constitutes a potential leak since cavities can remain in the vicinity of the cable, resulting in a leak due to thermal expansion of the air contained. The spacer according to the invention enables, on the other hand, an advantageous reduction of of cable passageways. An electric feed line only has to be inserted into the hollow chamber of the spacer one time, can be guided along the spacer frame of the glazing, and can be guided out of the main body of the spacer at any point of the glazing where a power supply is necessary. Thus, only a single entry point of the feed line must be sealed, even if a cable has to be routed into the glazing interior at various positions of the insulating glazing.

A substantial advantage of the invention also resides in the high degree of prefabrication of the spacer according to the invention having an integrated electrical feed line. The lines are already integrated into the spacer during the production process of the spacer such that during production of the insulating glazing, manual installation of the lines is no longer required. During production of the insulating glazing, the feed lines already present in the main body of the spacer only have to be guided out of the main body at the necessary points. For this purpose, the main body can, for example, be provided with a drilled hole through which the feed lines can be pulled out of the spacer. Since manual installation of the feed lines is eliminated, the degree of automation of the production of insulating glass can be further increased.

The hollow chamber is adjacent the glazing interior surface, with the glazing interior surface situated above the hollow chamber and the outer surface of the spacer situated below the hollow chamber. In this context, “above” is defined as facing the inner interpane space of the insulating glazing; and “below”, as facing away from the pane interior.

The hollow chamber of the spacer of the insulating glazing according to the invention results in a weight reduction in comparison with a solidly formed spacer and is available to accommodate additional components, for instance, a desiccant.

The first pane contact surface and the second pane contact surface are the sides of the spacer, on which the outer panes (first pane and second pane) of an insulating glazing are mounted at the time the spacer is installed. The first pane contact surface and the second pane contact surface run parallel to one another.

The glazing interior surface is defined as the surface of the spacer main body which points in the direction of the interior of the glazing after installation of the spacer in an insulating glazing. The glazing interior surface is between the first and the second pane.

The outer surface of the spacer main body is the side opposite the glazing interior surface that faces away from the interior of the insulating glazing in the direction of an outer seal.

The outer surface of the spacer can, in a possible embodiment, be angled in each case adjacent the pane contact surfaces, resulting in increased stability of the main body. The outer surface can be angled adjacent the pane contact surfaces, for example, by 30 to 60° in each case, relative to the outer surface.

In a preferred embodiment, the electric feed line enters the hollow chamber through an entry opening in the outer surface of the spacer. The positioning of the entry opening on the outer surface of the spacer is advantageous, since at this point a substantially flat surface is available, which can easily be resealed again after passage of the cable.

In another preferred embodiment, the electric feed line enters the hollow chamber through an open cross-section of the main body. In this case, the feed line is routed into the hollow chamber at an open end of the spacer. Here, preferably, a point is selected where a corner connector or a longitudinal connector is inserted into the spacer and and connects this to another spacer. The feed line is inserted together with one leg of the connector into the open cross-section of the main body. If necessary, the leg of the connector can have access that enables the feed line and the connector to be introduced into the open end of the spacer without spatial obstruction of the components. In this design as well, in order to achieve the highest possible tightness, the entry point of the feed line is sealed with a sealant.

In a preferred embodiment of the hollow profile spacer, the spacer includes a polymeric main body. This is advantageous since the thermal conductivity of plastics is significantly lower than the thermal conductivity of metals. Furthermore, the plastic of the polymeric main body has a specific resistance of at least 10⁸ Ωcm and is, consequently, non-conductive for electric current. This is particularly advantageous, since, in this case, the electric feed line requires no further insulation and the polymeric main body insulates the feed line sufficiently relative to other components.

Optionally, the polymeric main body can also have an electric feed line with insulation surrounding the feed line. This is advantageous, for example, to insulate multiple feed lines of different polarities running in the hollow chamber relative to each other.

In another preferred embodiment of the invention, the main body is a metallic main body. The metallic main body is preferably made of aluminum or stainless steel. With metallic main bodies, the electric feed line is surrounded by insulation which prevents a short-circuit between an electric feed line and the electrically conductive metallic main body.

The insulation has specific resistance less than or equal to 10⁸ Ωcm and preferably includes polyvinyl chloride, polyethylene, rubber, and/or polyurethane.

The electric feed line preferably extends in at least one section with a length of at least 10 cm, preferably at least 20 cm, particularly preferably at least 30 cm within the hollow chamber. This distance is accordingly situated at least between the entry opening and exit opening the farthest therefrom, measured along the longitudinal direction of the main body parallel to the pane contact surfaces. The advantages of the invention come into play particularly when longer sections of a feed line lying freely in the outer interpane space can be avoided since these are particularly cumbersome in the further processing of the insulating glazing.

The electric feed line is an electrical conductor, preferably containing copper. Other electrically conductive materials can also be used. Examples for this are aluminum, gold, silver, or tin and alloys thereof. The electric feed line can be designed both as a flat conductor and as a round conductor and, in both cases, as a single wire or multi-wire conductor (stranded wire).

The electric feed line preferably has a a conductor cross-section of 0.08 mm² to 2.5 mm².

Foil conductors can also be used as a feed line. Examples of foil conductors are described in DE 42 35 063 A1, DE 20 2004 019 286 U1, and DE 93 13 394 U1.

Flexible foil conductors, sometimes also called “flat conductors” or “flat band conductors”, are preferably made of a tinned copper strip with a thickness from 0.03 mm to 0.1 mm and a width from 2 mm to 16 mm. Copper has proven successful for such conductor tracks since it has good electrical conductivity as well as good processability into foils. At the same time, material costs are low.

Preferably, the spacer includes a polymeric main body, into which the electric feed line is already inserted during extrusion of the spacer. The main body is extruded around the electric feed line. This is particularly advantageous in terms of simple and economical production of the spacer and automated integration of the feed line into the main body.

In a particularly preferred embodiment, the electric feed line is already inserted into the polymeric main body during extrusion of the spacer, with the electric feed line materially bonded to the inner wall of the polymeric main body. The electric feed line can, for example, be introduced into the surface of the not yet solidified material of the polymeric main body during extrusion such that a material bond exists after solidification of the plastic. Alternatively, the surface of the electrical feed line adjacent the main body can be provided with an adhesive layer which bonds the electric feed line to the main body. For this, the electric feed line runs, for example, over an adhesive roller and is then enclosed by the polymeric main body. These embodiments are advantageous in terms of filling the cavity of the polymeric main body with desiccant. The electric feed lines rest directly against the wall of the main body such that the desiccant can be filled without hindrance and the formation of cavities without desiccant is avoided. Furthermore, in this way, the electric feed lines achieve a defined position within the main body. This is advantageous in terms of electrical contacting of the feed lines. In this way, the feed line can, for example, be attached to the inner wall of the main body adjacent the outer surface, and an electrical contact pin can be introduced starting from the outer surface through the wall of the polymeric main body into the electric feed line. In this way, an entry opening for the feed line is created and, at the same time, the electrical contact is made. For contacting by means of an electrical contact pin, strip-shaped conductors (e.g., foil conductors) are particularly suitable since they facilitate insertion of the contact pin. The electrical contact pin itself forms a section of the electrical feed line. The materials of the contact pin are, consequently, usually selected from the possible materials of the rest of the electric feed line. The electrical contact pin is, however, made of a solid material in order to facilitate pressing it into the polymeric main body. Electrical contacting of the feed line situated in the cavity from sides of the inner interpane space can also be done, analogously to what is described here, via a contact pin. The end of a contact pin protruding into the inner or outer interpane space can have a widened surface, for example, in the form of a metal plate, providing the possibility of connecting feed lines. Such a surface can, for example, serve as a soldering surface for connecting a cable that contacts the electrical load or the voltage source.

In a preferred embodiment, the length of the electric feed line exceeds the length of the spacer into which the feed line is integrated. This is advantageous in order to be able to pull the feed line out of the main body at an entry opening and/or an exit opening. Preferably, the length of the electric feed line is at least 5%, particularly preferably at least 10% longer than the length of the spacer into which the feed line is integrated. It has been found that this is sufficient for facilitating the routing of the feed line out of the spacer and to provide sufficient material along the spacer. The feed line can end flush with the open cross-section of the spacer, with the feed line laid, for example, in loops within the hollow chamber in order to integrate the longer feed line into the shorter spacer. Optionally, the electric feed line can protrude from the open cross-section of the spacer when the spacer is provided.

The electric feed line is suitable for being connected to a voltage supply at one end and to contact an electrical load at another end. After mounting the spacer according to the invention in an insulating glazing, the voltage supply is positioned outside the glazing interior; and the electrical load, within the glazing interior.

The electric feed line enters the glazing interior through an exit opening. The exit opening is preferably made in the glazing interior surface and/or in at least one of the pane contact surfaces. An exit opening in the glazing interior surface has the advantage that it does not have to be closed with a sealant, since a gas exchange between the hollow chamber of the spacer and the glazing interior is usually desirable. Moreover, the bonding between the spacer and adjacent panes is not adversely affected by the line routing. On the other hand, an exit opening on one of the pane contact surfaces is advantageous in order to optically conceal the exit opening and to position it at a point that is as inconspicuous as possible.

If the electric feed line is materially connected to the inner wall of a polymeric main body, this also provides the capability of making contact via an electrical contact pin. This is, for example, pressed into the polymeric main body on the glazing interior surface and protrudes into the electric feed line. Upon insertion of the contact pin, the exit opening is created at the same time. The contact pin provides the extension of the electric feed line into the glazing interior. The end of the contact pin situated in the glazing interior can be connected to an electric feed line by measures known to the person skilled in the art, for example, soldering or welding, which, in turn, serves to contact an electrical load in the interpane space.

In a particularly preferred embodiment, the spacer is a double spacer that can accommodate at least one additional pane in a groove. These are used, for example, for triple glazings in which the third pane is inserted in a groove between the first pane and the second pane. Such spacers are known from WO 2014/198431 A1, among others.

The double spacer comprises a main body with a first pane contact surface and a second pane contact surface extending parallel thereto, a glazing interior surface, and an outer surface. The basic structure corresponds to the spacer described for double glazings. The glazing interior surface is subdivided by the groove into two sub-regions. A first hollow chamber and a second hollow chamber that are separated from one another by the groove are introduced into the main body. The first hollow chamber is adjacent a first sub-region of the glazing interior surface, while the second hollow chamber is adjacent a second sub-region of the glazing interior surface, with the glazing interior surface situated above the hollow chambers and the outer surface situated below the hollow chambers. In this context, “above” is defined as facing the pane interior of an insulating glazing with a spacer according to the invention and “below” as facing away from the pane interior. Since the groove extends between the first glazing interior surface and the second glazing interior surface, it delimits them laterally and separates the first hollow chamber and the second hollow chamber from one another. The lateral flanks of the groove are formed by the walls of the first hollow chamber and the second hollow chamber. The groove forms a depression suitable for accommodating the middle pane (third pane) of an insulating glazing. The position of the third pane is thus defined by two lateral flanks of the groove and the bottom surface of the groove. A first and a second pane can be mounted on the first and second pane contact surface of the spacer.

The routing of the electric feed lines within the hollow chambers of a double spacer as well as their design details are analogous to the already described details of the spacer with a single hollow chamber. However, in the case of a spacer for triple or multiple glazings, there exists an additional possibility for positioning an exit opening of the electric feed line. The exit opening can be arranged not only on one of the pane contact surfaces and/or on the glazing interior surface, but can also be positioned within the groove. A spacer with multiple hollow chambers is also advantageous in that electric feed lines with different voltage potentials can be routed separately from one another in one hollow chamber in each case.

Optionally, the groove of a double spacer according to the invention includes an insert. The insert prevents slippage of the pane and resultant development of noise during the opening and closing of the window. The insert also compensates for thermal expansion of the third pane during warming such that, regardless of the climatic conditions, tension-free fixing is ensured. The insert can be recessed in the region of the electrical contacting in order to provide the space necessary for the contacting.

In a particularly preferred embodiment of the invention, the spacer is a spacer for triple glazings including at least one groove for accommodating a third pane, with the exit opening of the feed lines opening into the groove. This is advantageous, since, in the installed state of the spacer, the exit opening is not visible to the observer and, at the same time, the bonding of the spacer to the adjacent panes is unaffected.

Preferably, the exit opening is provided in at least one of the side flanks of the groove. An electric feed line emerging from the exit opening is then situated in the direct vicinity of the pane surface of a pane inserted into the groove. An electrically switchable functional element situated on this pane can thus be electrically conductively contacted with the electric feed line within the groove. The connection of the electrically switchable functional element to a voltage source is thus made in a region not visible to the observer.

In all embodiments described of the spacer according to the invention, a desiccant is introduced into the at least one hollow chamber such that any residual moisture in the insulating glazing is bound by the desiccant.

Preferably, the glazing interior surface of the spacer has at least one opening. Preferably, a plurality of openings are made in the glazing interior surface. The total number of openings depends on the size of the insulating glazing. The openings connect the hollow chambers to the interpane space, enabling a gas exchange between them. This allows absorption of atmospheric humidity by the desiccant situated in the hollow chambers and thus prevents fogging of the panes. The openings are preferably implemented as slits, particularly preferably as slits with a width of 0.2 mm and a length of 2 mm. The slits ensure optimum air exchange without desiccant being able to penetrate out of the hollow chambers into the inner interpane space.

If the spacer according to the invention has a polymeric main body, further measures for improving the gas tightness of the main body can be provided. Preferably, a gas- and vapor-tight barrier is applied at least on the outer surface of the polymeric main body, preferably on the outer surface and on a part of the pane contact surfaces. The gas- and vapor-tight barrier improves the tightness of the spacer against gas loss and moisture penetration. Preferably, the barrier is applied on approx. one-half to two-thirds of the pane contact surfaces. A suitable spacer with a polymeric main body is disclosed, for example, in WO 2013/104507 A1.

In a preferred embodiment, the gas- and vapor-tight barrier on the outer surface of a polymeric spacer is implemented as a film. This barrier film contains at least one polymeric layer as well as a metallic layer or a ceramic layer. The layer thickness of the polymeric layer is between 5 μm and 80 μm, whereas metallic layers and/or ceramic layers with a thickness of 10 nm to 200 nm are used. Within the layer thicknesses mentioned, particularly good tightness of the barrier film is achieved. The barrier film can be applied on the polymeric main body, for example, by gluing. Alternatively, the film can be coextruded together with the main body.

The barrier film particularly preferably contains at least two metallic layers and/or ceramic layers arranged alternatingly with at least one polymeric layer. The layer thicknesses of the individual layers are preferably as described in the preceding paragraph. Preferably, the outer layers are formed by the polymeric layer. In this arrangement, the metallic layers are particularly well protected against damage. The alternating layers of the barrier film can be bonded or applied on one another by a large variety of known prior art methods. Methods for depositing metallic or ceramic layers are well known to the person skilled in the art. The use of a barrier film with an alternating layer sequence is particularly advantageous in terms of the tightness of the system. A defect in one of the layers does not result in functional loss of the barrier film. In comparison, even a small defect in a single layer can result in a complete failure. Furthermore, the application of multiple thin layers is advantageous in comparison with one thick layer, since the risk of internal adhesion problems increases with increasing layer thickness. Also, thicker layers have higher conductivity such that such a film is less suitable thermodynamically.

The polymeric layer of the film preferably includes polyethylene terephthalate, ethylene vinyl alcohol, polyvinylidene chloride, polyamides, polyethylene, polypropylene, silicones, acrylonitriles, polyacrylates, polymethylacrylates, and/or copolymers or mixtures thereof. The metallic layer preferably includes iron, aluminum, silver, copper, gold, chromium, and/or alloys or oxides thereof. The ceramic layer of the film preferably contains silicon oxides and/or silicon nitrides.

In an alternative preferred embodiment, the gas- and vapor-tight barrier is preferably implemented as a coating. The coating contains aluminum, aluminum oxides, and/or silicon oxides and is preferably applied by a PVD method (physical vapor deposition). This can significantly simplify the manufacturing process since the polymeric main body is provided with the barrier coating immediately after manufacture, for example, by extrusion, and no separate step is necessary for applying a film. Coating with the materials mentioned provides particularly good results in terms of tightness and, additionally, exhibits excellent properties of adhesion to the materials of the outer seal used in insulating glazings.

In a particularly preferred embodiment, the gas- and vapor-tight barrier has at least one metallic layer or ceramic layer that is implemented as a coating and contains aluminum, aluminum oxides, and/or silicon oxides and is preferably applied by a PVD method (physical vapor deposition).

The polymeric main body preferably contains polyethylene (PE), polycarbonates (PC), polypropylene (PP), polystyrene, polybutadiene, polynitriles, polyesters, polyurethanes, polymethyl methacrylates, polyacrylates, polyamides, polyethylene terephthalate (PET), polybutylene terephthalate (PBT), preferably acrylonitrile butadiene styrene (ABS), acrylonitrile styrene acrylester (ASA), acrylonitrile butadiene styrene/polycarbonate (ABS/PC), styrene acrylonitrile (SAN), PET/PC, PBT/PC, and/or copolymers or mixtures thereof. Particularly good results are achieved with these materials.

The polymeric main body is preferably glass-fiber-reinforced. The coefficient of thermal expansion of the main body can be varied and adjusted by means of the selection of the glass fiber content in the main body. By adjusting the coefficient of thermal expansion of the polymeric main body and the barrier film or barrier coating, temperature-induced tensions among the various materials and spelling of the barrier film or coating can be avoided. The main body preferably has a glass fiber content of 20% to 50%, particularly preferably of 30% to 40%. At the same time, the glass fiber content in the polymeric main body improves strength and stability.

In another preferred embodiment, the polymeric main body is filled with hollow glass spheres or glass bubbles. These hollow glass spheres have a diameter of 10 μm to 20 μm and improve the stability of the polymeric hollow profile. Suitable glass spheres can be obtained commercially under the tradename “3M™ Glass Bubbles”. The polymeric main body particularly preferably contains polymers, glass fibers, and glass spheres. An admixture of glass spheres results in improvement of the thermal properties of the hollow profile.

The spacer preferably has, along the pane contact surfaces, a height of 5 mm to 15 mm, particularly preferably of 5 mm to 10 mm.

The width of the glazing interior surface, or the width of the sub-regions of the glazing interior surface, which defines the distance between two adjacent panes of the insulating glazing, is 4 mm to 30 mm, preferably 8 mm to 16 mm.

The invention further includes an insulating glazing with a spacer according to the invention. The insulating glazing comprises at least a first pane, a second pane, and a spacer according to the invention having an integrated electric feed line surrounding the panes.

The glazing interior of the insulating glazing is situated adjacent the glazing interior surface of the spacer. On the other hand, the outer surface of the spacer is adjacent the outer interpane space. The first pane is attached to the first pane contact surface of the spacer; and the second pane, to the second pane contact surface of the spacer.

The electric feed line integrated in the spacer of the insulating glazing enters the hollow chamber of the spacer from the outer interpane space and extends within the hollow chamber at least as far as a position in the edge seal of the insulating glazing where an electrical contact is desired. An electrically switchable functional element, whose voltage supply is to be ensured via the electric feed line, is situated in the glazing interior of the insulating glazing. For this purpose, the electric feed line enters the glazing interior between the first pane, the second pane, and the spacer at the desired point of the contacting through an exit opening in the wall of the main body. The electric feed line makes electrically conductive contact with the electrically switchable functional element in the glazing interior.

The first and the second pane are attached to the pane contact surfaces preferably via a sealant that is applied between the first pane contact surface on the first pane and/or the second pane contact surface and the second pane.

The sealant preferably contains butyl rubber, polyisobutylene, polyethylene vinyl alcohol, ethylene vinyl acetate, polyolefin rubber, polypropylene, polyethylene, copolymers, and/or mixtures thereof.

The sealant is preferably introduced into the gap between the spacer and the panes with a thickness of 0.1 mm to 0.8 mm, particularly preferably 0.2 mm to 0.4 mm.

The outer interpane space of the insulating glazing is preferably filled with an outer sealant. This outer sealant serves primarily for bonding the two panes and and thus for mechanical stability of the insulating glazing.

The outer sealant preferably contains polysulfides, silicones, silicone rubber, polyurethanes, polyacrylates, copolymers, and/or mixtures thereof. Such materials have very good adhesion to glass such that the outer sealant ensures secure bonding of the panes. The thickness of the outer sealant is preferably 2 mm to 30 mm, particularly preferably 5 mm to 10 mm.

The insulating glazing can also contain a plurality of electric feed lines which run through the main body of the spacer parallel to one another or also in different sections of the spacer. Preferably, all electric feed lines are introduced into the hollow chamber of the spacer at the same point, starting from the outer interpane space. This is advantageous since, thus, there is only a single entry opening and the risk of leaks in the edge seal is thus minimized.

Depending on the design of the electrically switchable functional element, there can be a plurality of electric feed lines of different polarity that make contact with the electrically switchable functional element at different positions.

The actual functional element having electrically switchable optical properties is formed at least by two electrically conductive layers and one active layer. The electrically conductive layers form surface electrodes. By applying a voltage to the surface electrodes, or by changing the voltage applied to the surface electrodes, the optical properties of the active layer, in particular the transmittance and/or the scattering of visible light can be influenced.

The electrically conductive layers are preferably transparent. The electrically conductive layers preferably contain at least a metal, a metal alloy, or a transparent conductive oxide (TCO). The electrically conductive layers preferably contain at least one transparent conductive oxide.

The electrically conductive layers preferably have a thickness of 10 nm to 2 μm, particularly preferably of 20 nm to 1 μm, most particularly preferably of 30 nm to 500 nm, and in particular of 50 nm to 200 nm. Thus, advantageous electrical contacting of the active layer is achieved.

The electrically conductive layers are intended to be electrically conductively connected to at least one external voltage source in order to serve as surface electrodes of the switchable functional element.

The actual switchable functional element can, in principle, be any functional element having electrically switchable properties known per se to the person skilled in the art. The design of the active layer depends on the type of functional element.

In an advantageous embodiment of the invention, an electrochromic functional element is contained in the inner interpane space. Here, the active layer of the multilayer film is an electrochemically active layer. The transmittance of visible light depends on the rate of ion storage in the active layer, with the ions provided, for example, by an ion storage layer between an active layer and a surface electrode. The transmittance can be influenced by the voltage applied to the surface electrodes, which causes a migration of the ions. Suitable active layers contain, for example, at least tungsten oxide or vanadium oxide. Electrochromic functional elements are known, for example, from WO 2012007334 A1, US 20120026573 A1, WO 2010147494 A1, and EP 1862849 A1.

In another advantageous embodiment of the invention, a PDLC functional element (polymer dispersed liquid crystal) is placed in the inner interpane space. The active layer contains liquid crystals that are, for example, embedded in a polymer matrix. When no voltage is applied to the surface electrodes, the liquid crystals are randomly oriented, resulting in strong scattering of the light passing through the active layer. When a voltage is applied to the surface electrodes, the liquid crystals align themselves in one common direction and the transmittance of light through the active layer is increased. Such a functional element is known, for example, from DE 102008026339 A1.

In another advantageous embodiment of the invention, the insulating glazing contains an electroluminescent functional element in the inner interpane space. The active layer contains electroluminescent materials that can be inorganic or organic (OLED). Applying a voltage on the surface electrodes excites the luminescence of the active layer. Such functional elements are known, for example, from US 2004227462 A1 and WO 2010112789 A2.

In another advantageous embodiment of the invention, the electrically switchable functional element is an SPD functional element (suspended particle device). The active layer contains suspended particles that are preferably embedded in a viscous matrix. The absorption of light by the active layer can be varied by applying a voltage on the surface electrodes, which results in a change in orientation of the suspended particles. Such functional elements are known, for example, from EP 0876608 B1 and WO 2011033313 A1.

In addition to the active layer and the electrically conductive layers, the electrically switchable functional element can, of course, have other layers known per se, for example, barrier layers, blocking layers, anti-reflection or reflection layers, protective layers, and/or smoothing layers.

The electrically switchable functional element can, alternatively, also include an electrically heatable coating, a photovoltaic coating integrated into the insulating glazing, and/or a thin-film transistor-based liquid crystal display (TFT-based LCD).

The electrically switchable functional element can be arranged at any desired point within the inner interpane space. Preferably, the electrically switchable functional element is situated on one of the surfaces of the panes of the insulating glazing situated in the inner interpane space.

In the case of a double glazing, the electrically switchable functional element is preferably attached to the surface of the first pane and/or the second pane facing the inner interpane space.

Particularly preferably, the insulating glazing according to the invention is a triple or multiple insulating glazing. In this case, the electrically switchable functional element is preferably applied on the third pane or additional other panes that are arranged between the first pane and the second pane.

In a particularly preferred embodiment of the invention, the insulating glazing includes at least three panes and a double spacer with a groove, in whose groove the third pane is inserted. The first and the second pane rest against the pane contact surfaces. In this case, the electrically switchable functional element is applied to one of the surfaces of the third pane. The electrical contacting between the feed line and the electrically switchable functional element occurs particularly advantageously within the groove. The electric feed line is routed out of the hollow chamber through an exit opening in the wall of the groove and routed within the groove to the electrically switchable functional element. The electrical contacting of the functional element is thus situated completely within the groove and is not visible to the observer after assembly of the insulating glazing.

The electrical connection of the feed line and the electrically conductive layers of the functional element is preferably done by so-called busbars, for example, strips of an electrically conductive material or electrically conductive imprints to which the electrically conductive layers are connected. The busbars are used to transfer electrical power and enable homogeneous voltage distribution. The busbars are advantageously produced by printing a conductive paste. The conductive paste preferably contains silver particles and glass frits. The layer thickness of the conductive paste is preferably from 5 μm to 20 μm.

In an alternative embodiment, thin and narrow metal foil strips or metal wires that preferably contain copper and/or aluminum are used as busbars; in particular, copper foil strips with a thickness of approx. 50 μm are used. The width of the copper foil strips is preferably 1 mm to 10 mm. The electrical contact between an electrically conductive layer of the functional element serving as a surface electrode and the busbar can be established, for example, by soldering or by gluing with an electrically conductive adhesive.

In an advantageous embodiment of the invention, a third pane having an electrically switchable functional element is inserted into the groove of a double spacer, with a busbar printed along the pane edge of the third pane. The busbar is dimensioned such that, after insertion of the pane into the groove of the spacer, the busbar is completely concealed by the groove. Accordingly, the height of the busbar, measured perpendicular to the nearest pane edge, is the height of the groove of the spacer minus the distance between the busbar and the nearest pane edge. Preferably, the groove has a height of 3 mm to 10 mm, particularly preferably 3 mm to 6 mm, for example, 5 mm, and the height of the busbar is 2 mm to 9 mm, preferably 2 mm to 5 mm. The distance from the busbar to the nearest pane edge is, for example, 1 mm.

Thus, even when using busbars, it is possible to make contact that is invisible to the observer within the groove. Alternatively, the busbar can still be positioned in the visible region of the pane and can be as far from the nearest pane edge as desired. Optionally, the busbar can be concealed by decorative elements, for example, a screen print.

Preferably, the double spacer with a groove has a polymeric main body, by which means a short-circuit between current-carrying components within the groove of the spacer and a metallic main body of the spacer is avoided. Alternatively, a metallic main body can also be used, provided appropriate insulation that prevents direct contact of the metallic main body with current-carrying components is inserted into the groove of the metallic main body. However, this is complex in the manufacturing process and entails potential sources of defects such that the use of polymeric main bodies is preferred, also in light of their further advantages in terms of reduced thermal conductivity.

Electrical contacting between an electric feed line and a busbar can either be indirect via contact elements or direct. Contact elements are used to achieve the best possible connection to the busbar in terms of mechanical stability of the connection and minimization of an undesirable voltage drop. Suitable means for electrically conductively fixing the contact element to the busbar are known to the person skilled in the art, for example, by soldering or gluing by means of a conductive adhesive.

Preferably, the contact element is implemented as a spring contact. This is particularly advantageous since this way there is a reversible connection of the contact element and the busbar, and the electrical contact between the contact element and the busbar is already made immediately by insertion of the pane carrying the busbar into the groove of the spacer.

The first pane, the second pane, and/or the third pane of the insulating glazing preferably contain glass, particularly preferably quartz glass, borosilicate glass, soda lime glass, and/or mixtures thereof. The first and/or second pane of the insulating glazing can also include thermoplastic polymeric panes. Thermoplastic polymeric panes preferably include polycarbonate, polymethyl methacrylate, and/or copolymers and/or mixtures thereof. Additional panes of the insulating glazing can have the same composition as mentioned for the first, second, and third pane.

The first pane and the second pane have a thickness of 2 mm to 50 mm, preferably 2 mm to 10 mm, particularly preferably 4 mm to 6 mm, with the two panes possibly even having different thicknesses.

The first pane, the second pane, and other panes can be made of single-pane safety glass, thermally or chemically toughened glass, float glass, extra-clear low-iron float glass, colored glass, or laminated safety glass including one or more of these components. The panes can have any other components or coatings desired, for example, low-E layers or other solar protection coatings.

The outer interpane space, delimited by the first pane, the second pane, and the outer surface of the spacer, is filled at least partially, preferably completely, with an outer seal. Very good mechanical stabilization of the edge seal is thus achieved. Furthermore, the seal surrounds the pressure equalization body and protects it against mechanical influences from the outside.

Preferably, the outer seal contains polymers or silane-modified polymers, particularly preferably organic polysulfides, silicones, room-temperature-vulcanizing (RTV) silicone rubber, peroxide-vulcanizing silicone rubber, and/or addition-vulcanizing silicone rubber, polyurethanes, and/or butyl rubber.

The sealant between the first pane contact surface and the first pane, or between the second pane contact surface and the second pane, preferably contains a polyisobutylene. The polyisobutylene can be a cross-linking or non-cross-linking polyisobutylene.

The insulating glazing is optionally filled with a protective gas, preferably with a noble gas, preferably argon or krypton, which reduce the heat transfer value in the insulating glazing interpane space.

In principle, a wide variety of geometries of the insulating glazing are possible, for example, rectangular, trapezoidal, and rounded shapes. For producing round geometries, the spacer can, for example, be bent in the heated state.

At the corners of the insulating glazing, the spacers are linked to one another, for example, via corner connectors. Such corner connectors can be implemented, for example, as molded plastic parts with a seal, in which two spacers abut. An electric feed line can, for example, be routed out of the main body of the spacer through the open cross-section of the spacer in the vicinity of its corner, routed along the corner connectors in the outer interpane space, and introduced again through the open cross-section of an adjacent spacer into its hollow chamber.

In another preferred embodiment, the spacer is not separated at the corners of the glazing and connected at the required angle by corner connectors, but, instead, is bent into the corresponding corner geometry under heating. This is advantageous since, in this way, there is a continuous hollow chamber all around along the edge of the glazing. The electric feed lines can thus be routed within the hollow chamber unobstructed even in the corner region.

The invention further includes a method for producing an insulating glazing according to the invention comprising the steps:
a) Providing a spacer having an integrated electric feed line,
b) Attaching the spacer between a first pane and a second pane in each case via a pane contact surface of the spacer by means of a sealant, and introducing an electrically switchable functional element into the glazing interior,
c) Pressing the pane assembly,
d) Introducing an outer seal into the outer interpane space.

In step b), the electric feed line makes electrically conductive contact with the electrically switchable functional element. For this, a section of the electric feed line is routed out of the spacer via an exit opening. Depending on its positioning, the exit opening can be produced during step b) or also before step b). An exit opening on the pane contact surfaces must be made before attaching the panes to the surfaces. Even if the exit opening is located on the glazing interior surface, it is preferably already produced before step b) since the panes do not act as an obstacle in this stage. The opening is preferably made in the form of a drilled hole in the main body of the spacer.

The electrically switchable functional element is introduced into the glazing interior at the same time as the attaching of the panes in step b) since it is usually attached on one of the surfaces of the panes located in the interior of the insulating glazing after assembly.

The bonding of the panes to the pane contact surfaces per step b) can be carried out in any order desired. Optionally, the bonding of the two panes to the pane contact surfaces can also be done simultaneously.

In step d), the outer interpane space is at least partially, preferably completely, filled with an outer seal. The outer seal is preferably extruded directly into the outer interpane space, for example, in the form of a plastic sealing compound.

Preferably, the glazing interior between the panes is filled with a protective gas before the pressing of the assembly (step c)).

Preferably, before step b), a desiccant is filled into the hollow chamber via the open cross-section of the spacer.

If the glazing to be produced is a multiple glazing with a double spacer including at least one groove, at least a third pane is inserted into the groove of the spacer before step b).

The invention further includes the use of a spacer according to the invention in insulating glazings including electrically switchable functional elements, particularly preferably in double or triple insulating glazings, in particular in double or triple insulating glazings including an SPD, a PDLC, an electrochromic, or an electroluminescent functional element. In all these glazings having electrically switchable components, a voltage supply into the glazing interior is necessary such that an electric feed line has to be routed from the outer interpane space into the glazing interior, which is significantly improved by the use of the spacer according to the invention.

The invention is explained in detail in the following with reference to drawings. The drawings are purely schematic representations and not to scale. They in no way restrict the invention. They depict:

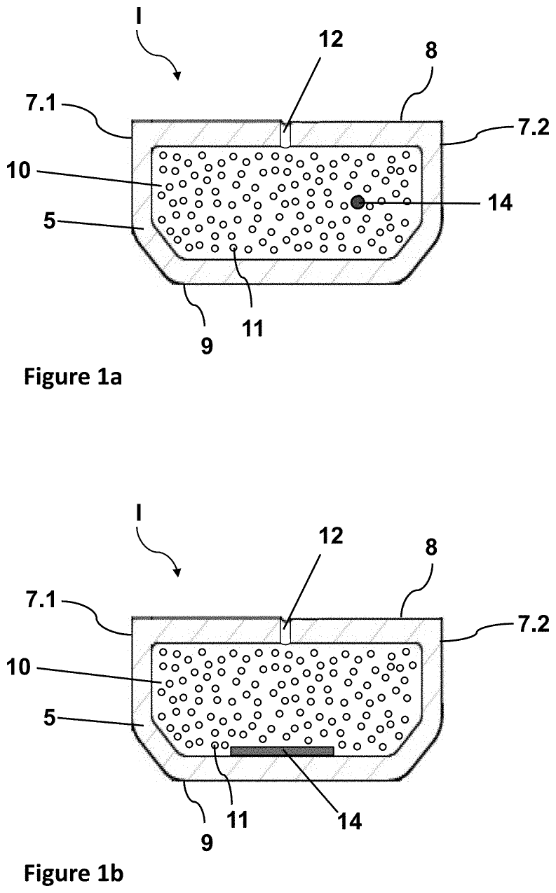

FIGS. 1a and 1b schematic representations of the spacer according to the invention in cross-section,

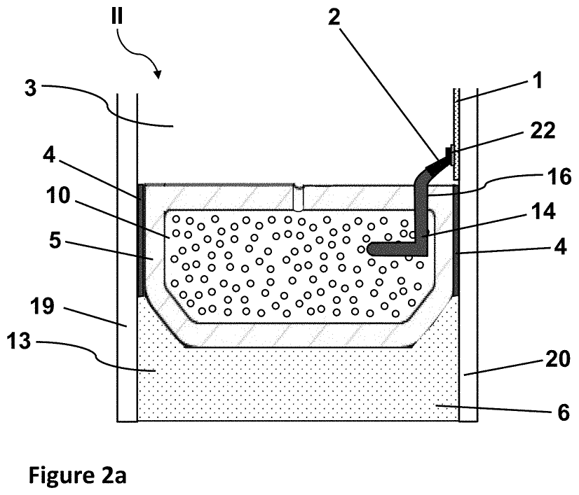

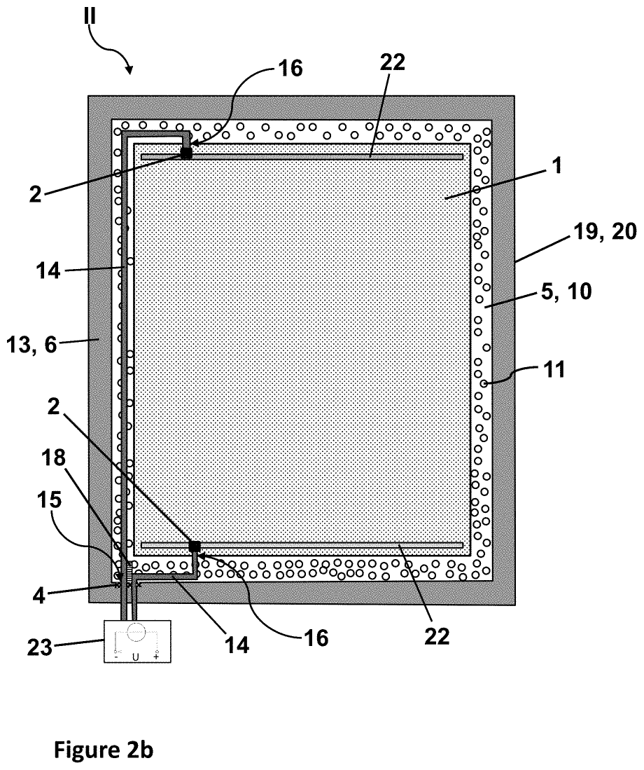

FIG. 2a a schematic representation of the insulating glazing according to the invention with a spacer according to FIG. 1 in cross-section,

FIG. 2b the insulating glazing according to the invention of FIG. 2a in an overall view,

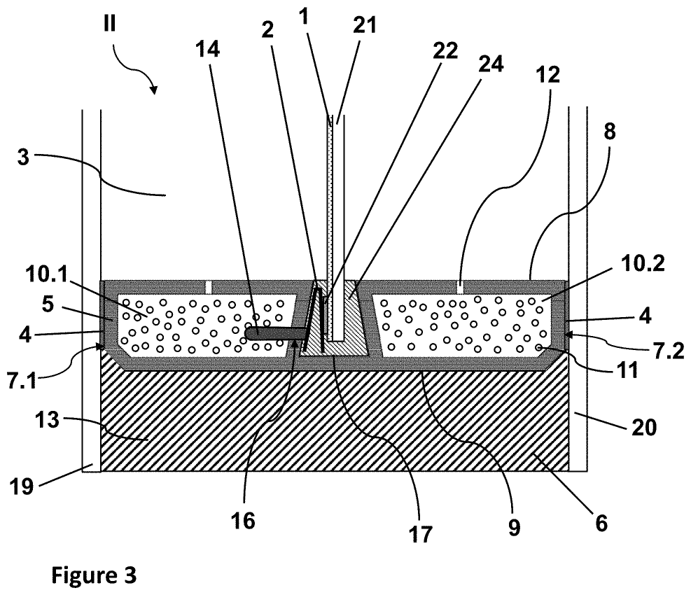

FIG. 3 an embodiment of a triple insulating glazing according to the invention with a double spacer in cross-section,

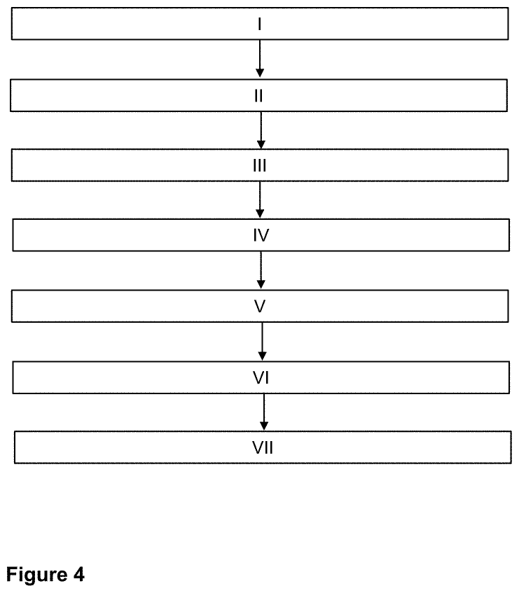

FIG. 4 a flow chart of a possible embodiment of the method according to the invention.

FIG. 1a depicts a schematic representation of the spacer I according to the invention comprising a polymeric main body 5 and an electric feed line 14 within the main body 5. The polymeric main body 5 is a hollow body profile comprising two pane contact surfaces 7.1 and 7.2, a glazing interior surface 8, an outer surface 9, and a hollow chamber 10. The polymeric main body 5 contains styrene acrylonitrile (SAN) and approx. 35 wt.-% glass fiber. The outer surface 9 has an angled shape, wherein the sections of the outer surface adjacent the pane contact surfaces 7.1 and 7.2 are inclined at angle of 30° relative to the pane contact surfaces 7.1 and 7.2. This improves the stability of the glass-fiber-reinforced polymeric main body 5. The hollow body 10 is filled with a desiccant 11. Molecular sieve is used as the desiccant 11. The glazing interior surface 8 of the spacer I has openings 12, which are made at regular intervals circumferentially along the glazing interior surface 8 to enable gas exchange between the interior of the insulating glazing and the hollow chamber 10. Thus, any atmospheric moisture present in the interior is absorbed by the desiccant 11. The openings 12 are implemented as slits with a width of 0.2 mm and a length of 2 mm. A barrier film (not shown) that reduces the heat transfer through the polymeric main body 5 into the glazing interior is applied on the outer surface 9 of the spacer I. The barrier film comprises four polymeric layers made of polyethylene terephthalate with a thickness of 12 μm and three metallic layers made of aluminum with a thickness of 50 nm. The metallic layers and the polymeric layers are placed alternatingly in each case, with the two outer layers formed by polymeric layers. The polymeric main body 5 is non-conductive for electric current such that the electric feed line 14 has no electrical insulation at all. The electric feed line 14 runs through the polymeric main body 5 over its entire length, which is, in the example of FIG. 1a, a length of 2.0 m. The electric feed line 14 protrudes from the main body 5 at both open cross-sections and has a total length of 2.2 m.

FIG. 1b depicts another embodiment of a spacer I according to the invention comprising a polymeric main body 5 and an electric feed line 14 within the main body 5. The spacer I of FIG. 1b corresponds to that described in FIG. 1a, wherein, in contrast thereto, the electric feed line 14 is materially connected to the inner wall of the polymeric main body 5 adjacent the outer surface 9. The electric feed line 14 is implemented as a metallic flat band conductor that was directly inserted into the polymeric main body 5 during extrusion thereof and is materially connected thereto. In this embodiment, it is possible to dispense with having the electric feed line 14 protrude beyond the length of the polymeric main body 5. The position of the electric feed line 14 is defined and fixed by the material connection such that electrical contact does not have to be made via a protruding end of the feed line, but, instead, the electric feed line 14 can, for example, be supplemented by a contact pin that is pressed through the outer surface 9 and the polymeric main body 5 into the conductor. The contact pin creates an entry opening and forms the extension of the feed line into the outer interpane space.

FIG. 2a depicts an insulating glazing II according to the invention with a spacer I in accordance with FIG. 1a. The spacer I according to the invention is mounted circumferentially between a first pane 19 and a second pane 20 via a sealant 4. The sealant 4 connects the pane contact surfaces 7.1 and 7.2 of the spacer Ito the panes 19 and 20. The glazing interior 3 adjacent the glazing interior surface 8 of the spacer I is defined as the space delimited by the panes 19, 20 and the spacer I. The outer interpane space 13 adjacent the outer surface 9 of the spacer I is a strip-shaped circumferential section of the glazing, which is delimited on one side each by the two panes 19, 20 and on another side by the spacer I, and its fourth edge is open. The glazing interior 3 is filled with argon. A sealant 4 that seals the gap between pane 19, 20 and spacer I is introduced in each case between a pane contact surface 7.1 or 7.2 and the adjacent pane 19 or 20. The sealant 4 is polyisobutylene. On the outer surface 9, an outer seal 6, which serves to bond the first pane 19 and the second pane 20, is applied in the outer interpane space 13. The outer seal 6 is made of silicone. The outer seal 6 ends flush with the pane edges of the first pane 19 and the second pane 20. On the pane facing the glazing interior 3, the second pane 20 has an electrically switchable functional element 1 that is equipped with a busbar 22 for the electrical contacting of the functional element 1. The electrically switchable functional element 1 is an electrochromic layer. During assembly in the insulating glazing II, an exit opening 16 was made in the spacer I of FIG. 1. This is in the vicinity of the busbar 22. The electric feed line 14 is pulled out through the exit opening 16 in the glazing interior surface 8 during assembly. The pulled-out conductor loop of the electric feed line 14 makes contact with the busbar 22 via a contact element 2. The contact element 2 is a so-called crimp connector, wherein the connection between the electric feed line 14 and the contact element 2 is made by squeezing the feed line into the crimp connector, and the opposite end of the crimp connector is soldered to the busbar 22. As a result of the routing according to the invention of the electric feed line 14 in the hollow chamber 10, the outer interpane space 13 is largely free of conductor lines such that unobstructed automated filling can be done with the outer seal 6. In another embodiment, the insulating glazing II of FIGS. 2a and 2b is particularly preferably realized with the spacer I of FIG. 1b (not shown in detail here). The connection between the electric feed line 14 and the contact element 2 is done via an electrical contact pin that is pressed into the glazing interior surface 8 and protrudes into the electric feed line 14 of FIG. 1b. The contact pin is connected via another section of the electric feed line (not shown) to the contact element 2 in the glazing interior 3.

FIG. 2b depicts an overall view of the insulating glazing II according to the invention in accordance with FIG. 2a. The contacting described in FIG. 2a of an electric feed line 14 running in the spacer I with the busbar 22 of the electrically switchable functional element 1 takes place at two opposite edges of the insulating glazing II. As described in FIG. 2a, at both edges, the electric feed line 14 enters into the glazing interior 3 through an exit opening 16 out of the hollow body 10 and makes electrically conductive contact with the busbar 22 via a contact element 2. The spacer I is bent at the corners of the insulating glazing II such that the hollow chamber 10 is continuous even at the corners of the glazing. Both electric feed lines 14 are routed within the main body 5 all the way to a common exit opening 15, where the feed lines 14 enter the outer interpane space 13 from the hollow chamber 10 and, from there out, are connected outside the glazing to a voltage source 23, in this case, a DC voltage source for operating an electrochromic functional element. The feed lines 14 are connected to different poles of the voltage source such that a difference in potential develops between the two opposite busbars 22. The voltage applied on the busbars 22 causes ion migration within the active layer of the electrochromic functional element, which influences its transmittance. The exit opening 15 is sealed with the sealant 4. Since the electric feed lines 14 of different polarity in the region of the exit opening 15 are located in the vicinity of one another, insulation 18 that prevents electrical contact between the two feed lines 14 is introduced in this area. The electric feed lines 14 run through the main body 5 along its entire circumference, since one spacer I, which was already extruded with an integrated electric feed line 14, was used for producing the spacer frame. For the sake of clarity, in FIG. 2a, only the sections of the electric feed line 14 used to connect the electrochromic functional element are shown. The insulating glazing II is preferably mounted in a window frame such that the exit opening 15 is positioned in the upper third of the insulating glazing in order to minimize the risk of water entering in the event of water accumulation.

FIG. 3 depicts an embodiment of a triple insulating glazing according to the invention with a double spacer, in cross-section. The basic structure of the insulating glazing II corresponds to that described in FIGS. 2a and 2b. In contrast thereto, the polymeric main body 5 has a groove 17 between the first pane contact surface 7.1 and the second pane contact surface 7.2, wherein there is a first hollow chamber 10.1 between the groove 17 and the first pane contact surface 7.1; and a second hollow chamber 10.2, between the groove 17 and the second pane contact surface 7.2. The side flanks of the groove 17 are formed by the walls of the two hollow chambers 10.1 and 10.2, whereas the bottom surface of the groove 17 is directly adjacent the outer surface 9. The groove 17 runs parallel to the pane contact surfaces 7. A third pane 21, which carries, on one pane surface, an electrically switchable functional element 1, here, also an electrochromic functional element with a busbar 22, is inserted into the groove 17 of the spacer I. The exit opening 16 is situated in one of the side flanks of the groove 17 and opens into the groove 17. In the groove 17, there is a contact element 2, which is implemented as a spring contact. The contact element 2 is already mounted in the groove 17 before insertion of the third pane 21. The third pane 21 is inserted into the groove 17 such that the busbar 22 points in the direction of the contact element 2. At the time of insertion of the third pane 21, the spring contact is pressed against the busbar 22, thus creating the desired electrical contact. The groove further contains an insert 24, which surrounds the edge of the third pane 21 and fits flush in the groove 17. The insert 24 is made of ethylene-propylene-diene rubber and is recessed in the region of the contact element 2. The insert 24 fixes the third pane 21 without tension and compensates for thermal expansion of the pane. In addition, the insert 24 prevents development of noise due to slippage of the third pane 21. The insulating glazing II according to the invention of FIG. 3 enables electrical contacting of the electrically switchable functional element that is invisible to the observer, with the busbar 22 also positioned completely within the groove 17 and concealed thereby.

FIG. 4 depicts a flow chart of a possible embodiment of the method according to the invention comprising the steps:
I Coextruding a polymeric spacer I with an integrated electric feed line 14,
II Prefabricating a circumferential spacer frame,
III Creating at least one exit opening 16 in the wall of the main body 5 and routing the electric feed line 14 out of main body 5,
IV Mounting a pane with an electrically switchable functional element 1 on the spacer I and making electrical contact of the electrical feed line 14 and the functional element 1,
V Mounting at least one more pane on the spacer,
VI Pressing the pane assembly, and
VII Inserting an outer seal 6 into the outer interpane space 13.

In a preferred embodiment, the electric feed line 14 in step I is mounted materially connected to the inner wall of the polymeric main body 5. Using the extrusion tool, a metallic conductor is inserted continuously into the hollow chamber during extrusion as an electric feed line, with the metallic conductor touching the material of the polymeric main body 5 and, thus, being materially bonded thereto after solidification of the plastic.

In step IV, in the case of a double glazing, a first pane 19 or a second pane 20 with an electrochromic functional element is attached to a pane contact surface 7 of the spacer I via a sealant 4. The electrochromic functional element faces in the direction of the subsequent glazing interior 3. In step V, the second pane 20 is then mounted on the still available pane contact surface 7, likewise by a sealant 4.

In the case of a triple glazing with a double spacer, in step IV, a third pane 21 is inserted into the groove 17 of the spacer I; and in step V, the first and the second pane 19 and 20 are mounted on the pane contact surfaces 7 via a sealant 4.

### LIST OF REFERENCE CHARACTERS

I spacer
II insulating glazing
1 electrically switchable functional element
2 contact element
3 glazing interior
4 sealant
5 polymeric main body
6 outer seal
7 pane contact surfaces
7.1 first pane contact surface
7.2 second pane contact surface
8 glazing interior surface
9 outer surface
10 hollow chambers
10.1 first hollow chamber
10.2 second hollow chamber
11 desiccant
12 openings
13 outer interpane space
14 electric feed line
15 entry opening
16 exit opening
17 groove
18 insulation
19 first pane
20 second pane
21 third pane
22 busbar
23 voltage source
24 insert

1. A spacer having an integrated electric feed line for insulating glazings comprising:
a main body comprising two pane contact surfaces, a glazing interior surface, an outer surface, a hollow chamber, and
an electric feed line within the hollow chamber,
wherein the electric feed line enters the hollow chamber, runs substantially parallel to the two pane contact surfaces in at least one section along the hollow chamber, and exits via at least one exit opening in a wall of the main body.

2. The spacer according to claim 1, wherein the electric feed line enters the hollow chamber through an entry opening in the outer surface of the spacer.

3. The spacer according to claim 1, wherein the electric feed line enters the hollow chamber through an open cross-section of the main body.

4. The spacer according to claim 1, wherein the main body is a polymeric main body, and the electric feed line is materially bonded to the inner wall of the polymeric main body.

5. The spacer according to claim 1, wherein the main body is a metallic main body and the electric feed line is surrounded by insulation.

6. The spacer according to claim 1, wherein the electric feed line runs through the hollow chamber in a section with a length of at least 10 cm.

7. The spacer according to claim 1, wherein the electric feed line exits through an exit opening in the glazing interior surface and/or through an exit opening in at least one of the two pane contact surfaces.

8. The spacer according to claim 1, wherein the spacer includes a groove for receiving a pane, which extends parallel to a first pane contact surface of the two pane contact surfaces and a second pane contact surface of the two pane contact surfaces, and a first hollow chamber is adjacent the groove and the first pane contact surface, and a second hollow chamber is adjacent the groove and the second pane contact surface, and wherein the electric feed line enters the groove through an exit opening.

9. An insulating glazing at least comprising a first pane and a second pane and a circumferential spacer according to claim 1 surrounding the first and second panes,
wherein
the first pane rests against a first pane contact surface of the two pane contact surfaces,
the second pane rests against a second pane contact surface of the two pane contact surfaces,
the electric feed line enters a glazing interior between the first pane, the second pane, and the spacer through the exit opening, and
the electric feed line makes electrically conductive contact with an electrically switchable functional element in the glazing interior.

10. An insulating glazing at least comprising a first pane, a second pane, and a third pane and a circumferential spacer according to claim 8 surrounding the first, second and third panes,
wherein
the first pane rests against a first pane contact surface of the two pane contact surfaces,
the second pane rests against a second pane contact surface of the two pane contact surfaces,
the third pane is inserted into the groove of the spacer,
the third pane includes an electrically switchable functional element, and
the electric feed line makes electrically conductive contact with the electrically switchable functional element within the groove.

11. The insulating glazing according to claim 9, wherein the electric feed line makes electrically conductive contact with the electrically switchable functional element via a contact element.

12. The insulating glazing according to claim 9, wherein the spacer is bent at corners of the insulating glazing and the at least one hollow chamber of the spacer is continuous circumferentially along the spacer.

13. A method for producing an insulating glazing according to claim 9, comprising
a) providing a spacer having an integrated electric feed line,
b) attaching the spacer by means of a sealant via the first and second pane contact surfaces between the first pane and the second pane, and inserting the electrically switchable functional element into the glazing interior so as to form an assembly,
c) pressing the assembly, and
d) introducing an outer seal into an outer interpane space, wherein, in step b), the electric feed line makes electrically conductive contact with the electrically switchable functional element.

14. The method according to claim 13, wherein, before step b), a third pane is inserted into a groove of the spacer.

15. A method comprising utilizing a spacer according to claim 1 in an insulating glazing including an electrically switchable functional element.

16. The spacer according to claim 6, wherein the length is at least 20 cm.

17. The spacer according to claim 16, wherein the length is at least 30 cm.

18. The insulating glazing according to claim 11, wherein the electric feed line makes electrically conductive contact with the electrically switchable functional element via a spring contact.

19. The method according to claim 15, wherein the electrically switchable functional element is a SPD, a PDLC, an electrochromic, or an electroluminescent functional element.
